(19) United States
(12) Patent Application Publication
(10) Pub. No.: US 2004/0153746 A1
(43) Pub. Date: Aug. 5, 2004

(54) Mechanisms for embedding and using integrity metadata

(76) Inventors: Nisha D. Talagala, Fremont, CA (US); Brian Wong, Gordonsville, VA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/633,234

(22) Filed: Jul. 31, 2003

Related U.S. Application Data
(63) Continuation-in-part of application No. 10/131,912, filed on Apr. 24, 2002.

(51) Int. Cl. H02H 3/05; G11C 29/00

(52) U.S. Cl. 714/8

(57) ABSTRACT

An embodiment of the present invention provides a method for validating data using version identifier IMD along with at least one other type of IMD embedded within a data block. Each type of IMD corresponds to a data verification operation. In conjunction, the multiple data verification operations protect against a larger class of data corruption errors than each would individually. For one embodiment, a data block is accessed, the data block being one of a plurality of data blocks mapped to a physical sector. Each of the data blocks contains a user data segment and an associated IMD segment. Each of the IMD segments includes a version identifier IMD and at least one other type of IMD. The data block is validated by verifying the version identifier IMD and at least one of the at least one other type of IMD.

### RELATED APPLICATIONS

This application is a continuation-in-part application of the co-pending U.S. Patent Application entitled Mechanisms for Embedding IMD Into Blocks, filed on Apr. 24, 2002, Ser. No. 10/131,912, assigned to the corporate assignee of the present invention.

### FIELD OF THE INVENTION

This invention relates generally to data storage systems and more particularly to the detection of corrupt data in such systems.

### BACKGROUND OF THE INVENTION

Typical large-scale data storage systems today include one or more dedicated computers and software systems to manage data. A primary concern of such data storage systems is that of data corruption and recovery. Data corruption may occur in which the data storage system returns erroneous data and doesn't realize that the data is wrong. Silent data corruption may result from hardware failures such as a malfunctioning data bus or corruption of the magnetic storage media that may cause a data bit to be inverted or lost. Silent data corruption may also result from a variety of other causes. In general, the more complex the data storage system, the more possible causes of silent data corruption.

Silent data corruption is particularly problematic. For example, when an application requests data and gets the wrong data, the application may crash. Additionally, the application may pass along the corrupted data to other applications. If left undetected, these errors may have disastrous consequences (e.g., irreparable, undetected, long-term data corruption).

The problem of detecting silent data corruption is addressed by creating integrity metadata (IMD) for each data block. The IMD may include a logical block address (LBA) to verify the location of the data block, or a checksum to verify the contents of a data block, or a version identifier as described in co-pending U.S. Patent Application entitled Mechanisms for Detecting Phantom Write Errors, filed on Aug. 15, 2002, Ser. No. 10/222,074, assigned to the corporate assignee of the present invention.

The issue of where to store the IMD arises. For example, a typical checksum together with other IMD may require 8-16 bytes. Typical data storage systems using block-based protocols (e.g., SCSI) store data in blocks of 512 bytes in length so that all input/output (I/O) operations take place in 512-byte blocks (sectors). One approach is simply to extend the block so that the checksum may be included. So, instead of data blocks of 512 bytes in length, the system will now use data blocks of 520 or 528 blocks in length depending on the size of the checksum. This approach has several drawbacks. The extended data block method requires that every component of the data storage system from the processing system, through a number of operating system software layers and hardware components, to the storage medium be able to accommodate the extended data block. Data storage systems are frequently comprised of components from a number of manufacturers. For example, while the processing system may be designed for an extended block size, it may be using software that is designed for a 512-byte block. Additionally, for large existing data stores that use a 512-byte data block, switching to an extended block size may require unacceptable transition costs and logistical difficulties.

Moreover, beyond the difficulty of where to store the IMD, is the fact that there are types of data corruption that are not amenable to detection given a particular one of the various error-detection types. For example, a simple checksum mechanism may be ineffectual or impractical for a particular example of silent data corruption resulting from a so-called “phantom write error.” This is because a phantom write error occurs when the data storage system fails to write the entire block of data to the requested location, leaving data at the requested location unchanged, as well as a corresponding checksum stored with the data. Accordingly, a checksum cannot be used to detect a phantom write error unless the checksum is stored separately from the data. However, such separated metadata would create a significant additional expense. Specifically, each read command would require at least two physical I/O operations (i.e., a data read and a metadata read) and each write command would require at least three physical I/O operations (i.e., a data write and three operations to update the metadata including read, modify and write). These read/modify/write operations are required because IMD is typically much smaller than a data block, and typical storage systems today only perform I/O operations in integral numbers of data blocks. If the data storage system contains redundant arrays of disk drives under RAID (“redundant arrays of inexpensive disks”) 1 or RAID 5 architectures, these additional operations can translate into many extra disk I/O operations.

The problem with the additional I/O operations can be ameliorated by caching the IMD in the memory of the data storage system. However, the IMD is typically 1-5 percent of the size of the data. For example, typical storage systems using block-based protocols (e.g., SCSI) store data in blocks of 512 bytes in length. Such data blocks would require 4-20 bytes of metadata for each data block (i.e., 10-50 MB of metadata for 1 GB of user data). Thus, it is not practical to keep all of the IMD in memory. Furthermore, even if it were possible to store the metadata in memory, metadata updates would need to be stored in a non-volatile storage device and would, therefore, require either additional disk I/O operations or non-volatile memory of a substantial size. It is possible to combine the storage of separated integrity metadata with specific data layouts, such as RAID 5. In such combinations, it is possible to reduce the I/O cost of metadata updates by combining these updates with other I/O operations required to maintain data redundancy. However, such techniques are limited in that they can only be used with a particular data layout. For example, a separated metadata storage technique that relies on a RAID 5 data layout will not be efficient for RAID 0, RAID 1, or any other data layout.

### SUMMARY OF THE INVENTION

An embodiment of the invention provides a method for validating data using version identifier IMD along with at least one other type of IMD embedded within a data block. In one exemplary embodiment of a method, a plurality of IMD segments is determined. Each IMD segment is associated with a segment of user data. The user data is then mapped to a plurality of physical sectors such that each physical sector contains a segment of user data and the associated IMD segment. For one embodiment, a data block is accessed, the data block being one of a plurality of data blocks mapped to a physical sector. Each of the data blocks contains a user data segment and an associated IMD segment. Each of the IMD segments includes a version identifier IMD and at least one other type of IMD. The data block is validated by verifying the version identifier IMD and at least one of the at least one other type of IMD.

In one embodiment, a data block of the common I/O data block size is mapped to a number of physical sectors, the number of physical sectors corresponding to the number of physical sectors required to store the data plus at least one additional physical sector. The mapping is accomplished such that each physical sector contains unused bytes and such that no physical sector contains data from more than one data block of the common I/O data block size. IMD pertaining to the data that has been mapped to each physical sector is determined. The IMD for each physical sector is then mapped into the unused bytes of each physical sector. Each physical sector now contains some of the original user data and the IMD associated with the data. Thus, an embodiment of the present invention employs a shrunken block method to store metadata in standard size blocks. For one embodiment, the IMD mapped to each sector includes a version identifier IMD as well as another type of IMD, such as a checksum IMD or an LBA IMD. In such an embodiment, validation of a data block is effected when the version identifier IMD, as well as the other type of IMD, is verified.

Other features and advantages of the present invention will be apparent from the accompanying drawings and from the detailed description that follow below.

### BRIEF DESCRIPTION OF THE DRAWINGS

The present invention is illustrated by way of example, and not limitation, by the figures of the accompanying drawings in which like references indicate similar elements and in which:

FIG. 1 illustrates “shrunken block” mapping in accordance with one embodiment of the present invention;

FIG. 2 illustrates the use of a shrunken block data block containing version identifier IMD as well as at least one other type of IMD in accordance with one embodiment of the invention;

FIG. 3 illustrates an exemplary data storage system in accordance with alternative embodiments of the present invention;

FIG. 4 is a process flow diagram in accordance with one embodiment of the present invention;

FIG. 5 is a process flow diagram in accordance with an alternative embodiment of the present invention;

FIG. 6 illustrates the data mapping in accordance with one embodiment of the present invention; and

FIG. 7 illustrates a process by which the version identifier IMD and at least one other type of IMD of each data block are used in conjunction to verify the integrity of a data block in accordance with an embodiment of the present invention.

### DETAILED DESCRIPTION

### Overview

An embodiment of the present invention provides a method for validating data using version identifier IMD along with at least one other type of IMD embedded within a data block. Each type of IMD corresponds to a data verification operation. In conjunction, the multiple data verification operations protect against a larger class of data corruption errors than each would individually. In accordance with one embodiment, the 512-byte block size is retained. A portion of the data of a block, along with the associated IMD, is mapped to a 512-byte sector. The remaining data from the block is mapped to the next 512-byte sector. That is, the user data part of each physical sector is shrunken to accommodate the IMD and the user data is distributed over more physical sectors. In one embodiment, a common I/O data block size for the data storage system is determined. The data from a data block of the common I/O data block size is mapped into a number of 512-byte sectors. The number of 512-byte sectors corresponds to the number required for the common I/O data block size plus one or more additional 512-byte sectors. This creates additional space in each sector to accommodate the IMD. That is, each physical sector contains unused bytes. IMD for each data segment of the common I/O size is determined. The IMD for each sector is then mapped to the additional space of each sector. In one embodiment, 8 kilobytes (K bytes) of data and its accompanying IMD are mapped to seventeen 512-byte sectors.

In the following description, numerous specific details are set forth. However, it is understood that embodiments of the invention may be practiced without these specific details. In other instances, well-known circuits, structures and techniques have not been shown in detail in order not to obscure the understanding of this description.

Reference throughout the specification to “one embodiment” or “an embodiment” means that a particular feature, structure, or characteristic described in connection with the embodiment is included in at least one embodiment of the present invention. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments.

Similarly, it should be appreciated that in the foregoing description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

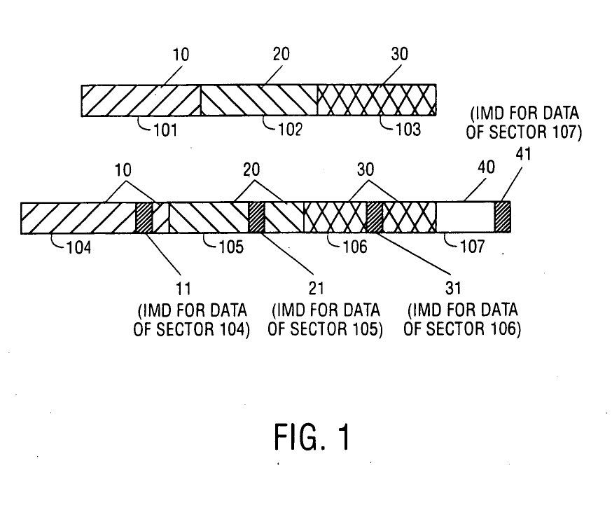

FIG. 1 illustrates “shrunken block” mapping in accordance with one embodiment of the present invention. As shown in FIG. 1, three 512-byte data blocks, namely 10, 20 and 30 are mapped into three 512-byte sectors, 101, 102 and 103, respectively. Data blocks 10, 20 and 30 do not include IMD. In order to include the IMD using the shrunken block method, the data is remapped to more sectors. Upon remapping, sector 104 includes a portion of the data from data block 10 as well as the IMD 11. IMD 11 is the IMD pertaining to the data mapped to sector 104. The remainder of data from data block 10 is included in a subsequent sector, e.g., sector 105. Sector 105 also includes a portion of the data from data block 20 as well as the IMD 21. IMD 21 is the IMD pertaining to the data mapped to sector 105. The remainder of data from data block 20 is included in sector 106. Sector 106 also includes a portion of the data from data block 30 as well as the IMD 31. IMD 31 is the IMD pertaining to the data mapped to sector 106. The remainder of data from data block 30 is included in sector 107. Sector 107 also includes a portion of the data from data block 40 as well as the IMD 41. IMD 41 is the IMD pertaining to the data mapped to sector 107.

The shrunken block method of embedding IMD may require additional I/O operations. For example, if the original data block is remapped over more than one physical sector such that a single physical sector contains data from more than one original data block, write operations to the data block will now require a read/modify/write operation. This is because the storage system will effect I/O operations in the fixed block size (i.e., 512 bytes). In the current storage environment, it is not normal for systems to perform operations on data items whose size is not a multiple of the fixed sector size, although it is possible to create such a system.

In accordance with various embodiments of the invention, version identifier IMD as well as at least one other type of IMD are stored with a portion of the data from the original data block. It will be appreciated that a variety of types of IMD may be included with the version identifier IMD in the data block in accordance with various embodiments of the invention. A brief description of version identifier IMD, as well as other exemplary types of IMD, is provided below.

### Version Identifier

Each data block stored on a storage medium is associated with two version identifiers. The first version identifier is stored within the data block and the second version identifier is stored outside of the data block. When a WRITE operation pertaining to the data block is received, a next version value associated with the data block is determined and this version value is written to each version identifier during the execution of the WRITE operation. If a phantom write error occurs during the execution of the WRITE operation, the next version value will be written to the version identifier stored outside of the data block, but not the version identifier stored within the data block. This mismatch between the two version identifiers will indicate the possible occurrence of the phantom write error. When a READ operation pertaining to the data block is received, the two version identifiers are compared. If the version identifiers do not match, data corruption has occurred.

### Logical Block Address

An LBA is stored with the data. When the data is accessed from the storage system, the LBA stored with the data is compared to the LBA (i.e., the LBA provided to the storage system to access the data). If the two LBAs are not identical, then data corruption has occurred. The LBA IMD can be used to detect a misdirected I/O operation.

### Checksum

A checksum is a numerical value derived through a mathematical computation on the data in a data block. When data is stored, a numerical value is computed and associated with the stored data. When the data is subsequently read, the same computation is applied to the data. If the result is not an identical checksum, then data corruption has occurred. Alternatively, a mathematical formula may be used such that when the formula is applied to the data and the checksum together, a predetermined value will result for valid data. If, upon application of the formula, the predetermined value does not result, then data corruption has occurred. Checksum algorithms are developed to minimize the probability that the checksum and its associated data will be corrupted in the same way. The strength of a checksum determines how likely it is that a data block experiencing a typical type of error will not result in a data block with an identical checksum. The checksum IMD may be used to detect an erroneous WRITE operation.

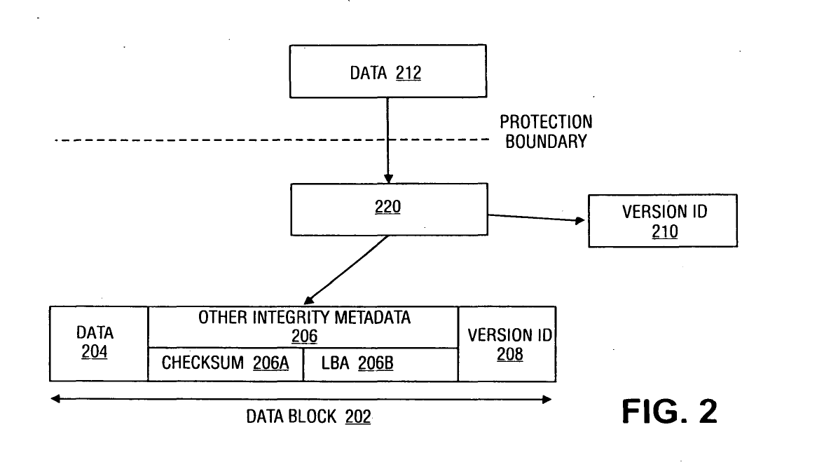

FIG. 2 illustrates the use of a shrunken block data block containing version identifier IMD as well as at least one other type of IMD in accordance with one embodiment of the invention. The data block 202 shown in FIG. 2, includes data 204 and an associated version identifier IMD 208 as well as other types IMD 206 shown as check sum 206A and LBA 206B. Data block 202 is also associated with version identifier 210 that is stored outside of data block 202. In one embodiment, version identifier 210 is stored in a non-volatile storage such as NVRAM or flash memory. Alternatively, version identifier 210 is stored on a disk and may be cached in volatile memory. The IMD 206 may pertain to both the data 204 and the version identifier 208.

When a command to write data 212 to data block 202 is issued, version identifier functionality 220 determines a next version identifier value for data block 202, and writes this next version identifier value to version identifier 210 and version identifier 208 while writing data 212 to data block 202. If the execution of write command to data block 202 fails (i.e., data corruption such as a phantom write error occurs), the next version identifier value will be written to version identifier 210 but not version identifier 208, resulting in mismatch between version identifiers 208 and 210. When data 204 is subsequently read, this mismatch will indicate the possible occurrence of a phantom write error. As will described in more detail below, when the mismatch is detected, there is a high likelihood that the mismatch was caused by a phantom write error. In one embodiment, version identifier functionality 220 considers each mismatch to be caused by a phantom write error. Alternatively, version identifier functionality 220 performs further analyses to determine the actual cause of the mismatch as will be described in greater detail below. On a WRITE operation, it is also possible to verify the existing versions by doing an extra READ operation (of the old data) and comparing it with the existing separated version identifier. After the verification is complete, the version identifier can be incremented for the next WRITE. This detects a phantom write that is about to take place, which may optionally be aborted.

In one embodiment, each of version identifiers 208 and 210 is a one-bit field. Such size is likely to result in a cumulative space of version identifiers 210 that is sufficiently small to be kept in NVRAM or other fast non-volatile storage. For example, for common data blocks of 512 bytes in length, 1 TB of user data will require 256 MB of version identifier data. One-bit version identifiers allow the detection of a single occurrence of a phantom write error or an odd number of consecutive occurrences of a phantom write error (e.g., three consecutive occurrences of the error). However, one-bit version identifiers cannot be used to detect an even number of consecutive occurrences of a phantom write error (e.g., two consecutive occurrences of the error).

In another embodiment, two-bit version identifiers are used to allow the detection of any number of consecutive phantom write errors that is not a multiple of four. In yet another embodiment, larger version identifiers (e.g., three-bit or four-bit version identifiers) can be used to detect more back-to-back errors. In yet another embodiment, version identifiers can store unique identifiers of data block versions (e.g., timestamps or version numbers).

In one embodiment, the size of version identifiers is determined by balancing memory constraints and frequency of consecutive phantom write errors in a particular data storage system.

### System

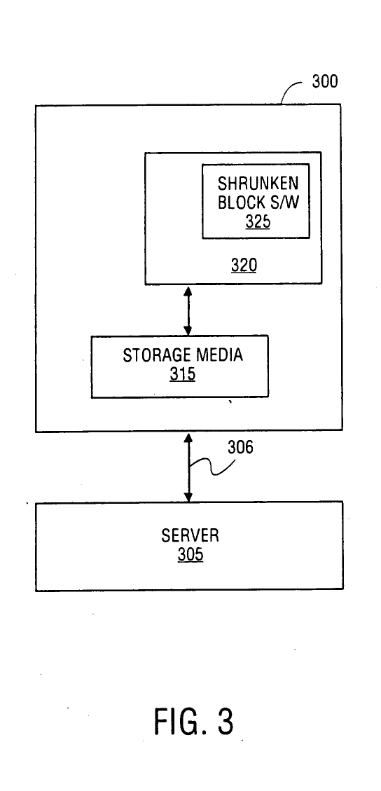

FIG. 3 illustrates an exemplary data storage system in accordance with an embodiment of the present invention. The method of the present invention may be implemented on the data storage system shown in FIG. 3. The data storage system 300 shown in FIG. 3 contains one or more mass storage devices 315 that may be magnetic or optical storage media. Data storage system 300 also contains one or more internal processors, shown collectively as the CPU 320. The CPU 320 may include a control unit, arithmetic unit and several registers with which to process information. CPU 320 provides the capability for data storage system 300 to perform tasks and execute software programs stored within the data storage system. The process of embedding IMD within a data block in accordance with the present invention may be implemented by hardware and/or software contained within the data storage device 300. For example, the CPU 320 may contain a memory 325 that may be random access memory (RAM), or some other machine-readable medium, for storing program code such as shrunken block software or data validation software that may be executed by CPU 320.

For one embodiment, the data storage system 300, shown in FIG. 3, may include a processing system 305 (such as a PC, workstation, server, mainframe or host system). Users of the data storage system may be connected to the server 305 via a local area network (not shown). The data storage system 300 communicates with the processing system 305 via a bus 306 that may be a standard bus for communicating information and signals and may implement a block-based protocol (e.g., SCSI or fibre channel). The CPU 320 is capable of responding to commands from processing system 305.

It is understood that many alternative configurations for a data storage system in accordance with alternative embodiments are possible. For example, the embodiment shown in FIG. 3 may, in the alternative, have the shrunken block software implemented in the processing system. The shrunken block software may, alternatively be implemented in the host system.

### Process

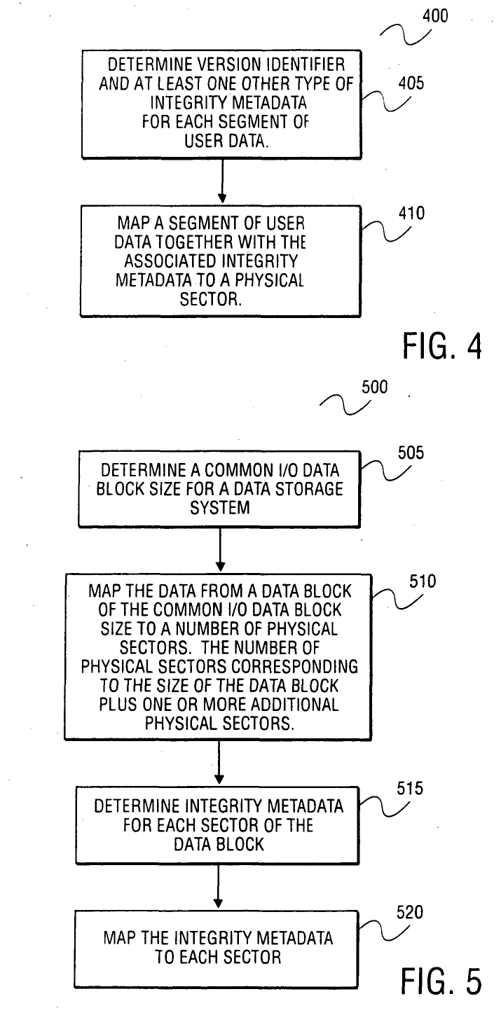

FIG. 4 is a process flow diagram in accordance with one embodiment of the present invention. Process 400, shown in FIG. 4, begins with operation 405 in which version identifier IMD and at least one other type of IMD is determined for each segment of user data. IMD may typically be 2-3 percent of the size of the user data to which it pertains. At operation 410 a segment of user data and its associated IMD are mapped to a physical sector. That is, a segment length for a segment of user data is selected such that the user data and the IMD segment associated with it, together, fill a physical sector of a data storage system. For example, typical systems use a 512 byte physical sector. The IMD segment may be 16 bytes in length. This yields a user data segment of 496 bytes in length. That is, 496 bytes of user data, together with the 16 bytes of IMD pertaining to it, are mapped to a 512 byte physical sector. In an alternative embodiment, the length of the metadata segment and/or the size of the physical sector may be different, thus resulting in a different segment length of the user data.

For one embodiment, the user data may have been originally mapped such that each segment of user data filled a physical sector. For such an embodiment, a portion of the original data segment together with the IMD pertaining to the portion are mapped to a physical sector. The remainder of the original segment is mapped to a subsequent physical sector as described above in reference to FIG. 1.

FIG. 5 is a process flow diagram in accordance with one such embodiment of the present invention. Process 500, shown in FIG. 5, begins with operation 505 in which a common I/O data block size is determined for a data storage system. Typically, data storage systems have a common I/O data block size in which many of their I/O operations take place. So even though storage systems effect I/O operations in 512 byte sectors, many systems have a common I/O data block size that is some multiple of 512 bytes. In a typical system, a majority of I/O operations may take place using the common I/O data block size. For example, the Solaris data storage system manufactured by Sun Microsystems, Inc. of Santa Clara, Calif. has a common I/O data block size of 8K bytes that may account for up to 80 percent of I/O operations.

At operation 510 the data from the common I/O size data block is mapped to a number of physical sectors. These physical sectors could be 512 bytes in length. The number of 512-byte sectors corresponds to the number required for the common I/O data block size plus one or more additional 512-byte sectors. This creates additional space in each sector to accommodate the IMD. That is, each physical sector will have unused bytes due to mapping the data block into more physical sectors than are required to store the data. For example, for a common I/O size data block of 8K bytes, the 8K bytes of data may be mapped into 17 512-byte sectors, thus leaving 30 unused bytes for each sector. The amount of space allocated for IMD in each physical sector is determined by the mapping and may result in more space than required for the actual IMD. If the space allocated for an IMD cannot be divided evenly between all physical sectors, there will be some available space at the end of the last sector.

In an alternative embodiment, more than one additional 512-byte sector is added to the data block of the common I/O data block size. This may be done to accommodate a greater amount of IMD. For example, for a common I/O data block size of 8K, if the IMD for each sector is more than 30 bytes in length, then an additional sector or sectors would be added to the data block. Also, if the common I/O data block size is larger, an additional sector or sectors may be required. For example, if the common I/O data block size is 32K bytes, then IMD of only 8 bytes for each 512-byte sector would require the addition of two sectors.

At operation 515 version identifier IMD and at least one other type of IMD is determined for each 512-byte sector of the data block. The at least one other type of IMD may be a checksum, or an LBA, or other IMD as known in the art, or any combination thereof. In accordance with an embodiment of the present invention, each data block of the common I/O data block size will require at least one 512-byte sector allocated for metadata. The version identifier IMD and the at least one other type of IMD may then be verified by several layers of software in the storage system or I/O stack.

At operation 520 the version identifier IMD and at least one other type of IMD are mapped to the additional space in each sector allocated for IMD. The entire data block together with its associated IMD is now mapped into 512 byte physical sectors. Each I/O data block starts at a physical sector boundary, and two data blocks never share a physical sector. The use of 512 byte physical sectors in the preceding description of an embodiment is exemplary. The method of FIG. 5 can also be performed for sector sizes other than 512 bytes. For example, sector sizes of 4096 could be used.

The embedded version identifier IMD and at least one other type of IMD are now available to any software layer or hardware component that wishes to verify the data-metadata relationship. In contrast to the prior art, the block size has not been changed and therefore any software layer or hardware component that is unaware of the presence of the IMD may simply treat the block as if it were all data. No changes to existing APIs or underlying storage devices are required.

Additionally, for the common I/O data block, a data storage system may now avoid the additional I/O operations incumbent when a data block is distributed over multiple physical sectors. That is, a write to the data block is affected by a single write operation and does not include the additional I/O operations (i.e., read/modify/write) of the shrunken block method. This applies to I/O operations of the common size. However, the common I/O data block size may account for a vast majority of I/O operations.

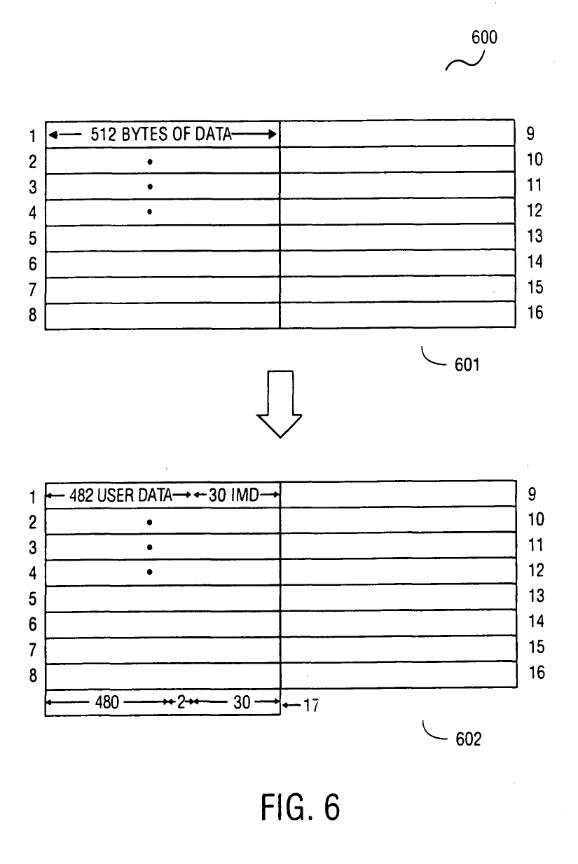

FIG. 6 illustrates the data mapping in accordance with one embodiment of the present invention. The data mapping begins with a common I/O size data block mapped into a number of physical sectors. Data block 601, shown in FIG. 6, illustrates a common I/O data block size of 8K bytes mapped into 16 512 byte physical sectors, sectors 1-16. Each of the 16 physical sectors contains 512 bytes of user data.

As discussed above in reference to operation 510 of FIG. 5, the user data is remapped to a number of physical sectors. Data block 602 illustrates the data from data block 601 remapped into 17 512-byte sectors in accordance with one embodiment of the present invention. As shown in data block 602, 16 of the sectors now contain 482 bytes of user data, with the last sector (sector 17) containing the remaining 480 bytes of user data and 2 unused bytes. As discussed above in reference to operations 515 and 520 of FIG. 5, the version identifier IMD and at least one other type of IMD are determined for each of the 17 482-byte sectors of data block 602 and the version identifier IMD and at least one other type of IMD for each sector are mapped into the 30 byte segment of unused space within the physical sector. Thus, each physical sector now contains user data and its associated IMD and data blocks of a common I/O size are mapped to an integral number of physical sectors.

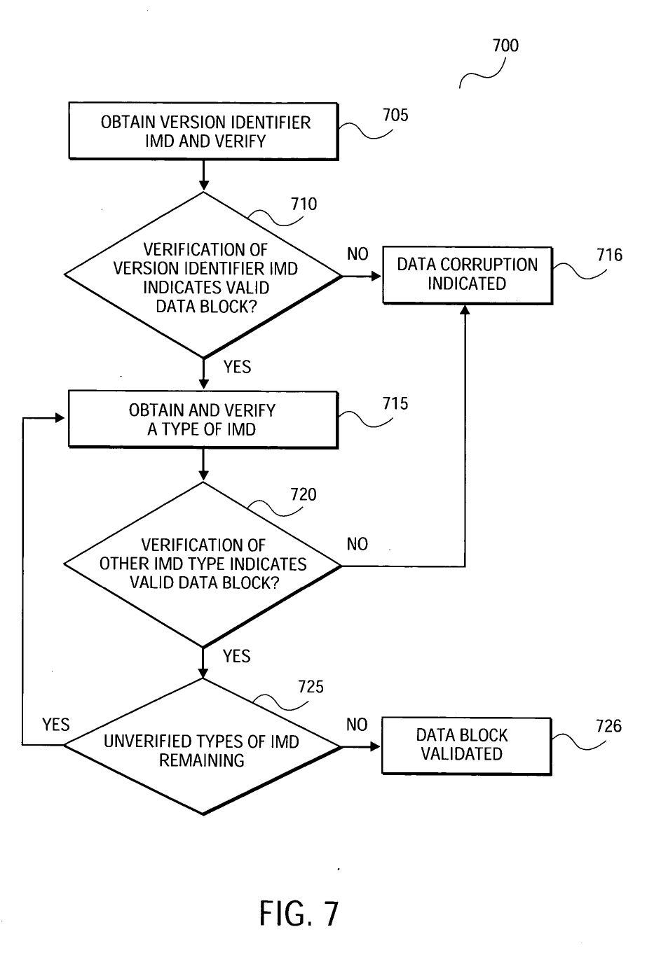

FIG. 7 illustrates a process by which the version identifier IMD and at least one other type of IMD of each data block are used in conjunction to validate the integrity of a data block in accordance with an embodiment of the present invention. Process 700, shown in FIG. 7, begins with operation 705 in which the version identifier IMD for a particular data block is obtained and verified. This operation may be in response to a READ operation pertaining to the data block, and may consist of comparing the version identifier stored within the data block to a copy of the version identifier stored elsewhere as described above in reference to FIG. 2.

At operation 710, if the version identifier IMD is not verified (e.g., the version identifier stored within the data block does not match the copy of the version identifier stored elsewhere), data corruption is indicated at operation 716. If, at operation 710, the version identifier IMD is verified (e.g., the version identifier stored within the data block matches the copy of the version identifier stored elsewhere), the process continues with obtaining and verifying at least one other type of IMD stored within the data block.

At operation 715 another type of IMD stored within the data block is obtained and verified. The verification process for each type of IMD depends upon the particular type of IMD. For example, a checksum may be verified by subjecting the data within the data block to the same mathematical calculation used to create the checksum IMD, or by other methods known in the art as described above. A LBA IMD may be verified by comparison to the LBA used to access the data block, as described above. It will be appreciated that the verification process appropriate to each type of IMD is applied for that particular IMD.

At operation 720, if the other type of IMD is not verified (e.g., the LBA used to access the data block does not match the LBA stored within the data block), data corruption is indicated at operation 716. If, at operation 720, the other type of IMD is verified (e.g., the LBA used to access the data block matches the LBA stored within the data block), the process continues with obtaining and verifying additional other types of IMD stored within the data block, if any.

The process continues at operation 725 until all of the types of IMD stored within the data block have been verified. When all of the types of IMD stored within the data block have been verified, the data block is validated at operation 726.

### General Matters

Embodiments of the invention may be applied to provide methods for storing version identifier IMD as well as one other type of IMD within a data block to provide detection of an increased variety of data corruption. To effect this, a shrunken block data mapping scheme is implemented in which the each data block contains user data and version identifier IMD as well as at least one other type of IMD. The version identifier IMD and the at least one other type of IMD are used in conjunction to detect data corruption. For one embodiment, the validation of a data block is effected when the version identifier IMD as well as the other types of IMD is verified. For one embodiment, each data block contains version identifier IMD as well as checksum IMD. In another embodiment each data block contains version identifier IMD as well as LBA IMD. In still another embodiment, each data block contains version identifier IMD, checksum IMD, and LBA IMD.

For alternative embodiments only the version identifier IMD and specified other types of IMD are verified to validate the data block. For such embodiments, the specification of the type of IMD may be based upon an expected type of data corruption.

Various alternative embodiments of the method of the invention may be implemented anywhere within the block-based portion of the I/O datapath. The datapath includes all software, hardware, or other entities that manipulate the data from the time that it enters block form on write operations to the point where it leaves block form on read operations. The datapath extends from the computer that reads or writes the data (converting it into block form) to the storage device where the data resides during storage. For example, the datapath includes software modules that stripe or replicate the data, the disk arrays that store or cache the data blocks, the portion of the file system that manages data in blocks, the network that transfers the blocks, etc.

The invention includes various operations. It will be apparent to those skilled in the art that the operations of the invention may be performed by hardware components or may be embodied in machine-executable instructions, which may be used to cause general-purpose or special-purpose processor or logic circuits programmed with the instructions to perform the operations. Alternatively, the steps may be performed by a combination of hardware and software. The invention may be provided as a computer program product that may include a machine-readable medium having stored thereon instructions, which may be used to program a computer (or other electronic devices) to perform a process according to the invention. The machine-readable medium may include, but is not limited to, floppy diskettes, optical disks, CD-ROMs, and magneto-optical disks, ROMs, RAMs, EPROMs, EEPROMs, magnet or optical cards, flash memory, or other type of media/machine-readable medium suitable for storing electronic instructions. Moreover, the invention may also be downloaded as a computer program product, wherein the program may be transferred from a remote computer to a requesting computer by way of data signals embodied in a carrier wave or other propagation medium via a communication cell (e.g., a modem or network connection).

While the invention has been described in terms of several embodiments, those skilled in the art will recognize that the invention is not limited to the embodiments described, but can be practiced with modification and alteration within the spirit and scope of the appended claims. The specification and drawings are, accordingly, to be regarded in an illustrative sense rather than a restrictive sense.

What is claimed is:

1. A method comprising:
accessing a data block, the data block one of a plurality of data blocks mapped to a physical sector, each data block containing a user data segment and an associated IMD segment, each IMD segment including a version identifier IMD and at least one other type of IMD; and
validating the data block by verifying the version identifier IMD and at least one of the at least one other type of IMD.

2. The method of claim 1, wherein the at least one other type of IMD comprises checksum IMD.

3. The method of claim 1, wherein the at least one other type of IMD comprises logical block address IMD.

4. The method of claim 1, wherein the at least one other type of IMD comprises checksum IMD and logical block address IMD.

5. The method of claim 1 wherein verifying the version identifier IMD includes determining that a first version identifier stored within the data block matches a second version identifier stored outside of the data block.

6. The method of claim 2 wherein verifying the checksum IMD includes determining that a checksum stored within the data block matches a checksum obtained by applying a process to a user data contained within the user data segment of the data block, the process being a same process used to create the checksum IMD.

7. The method of claim 3 wherein verifying the logical block address IMD includes determining that a logical block address stored within the data block matches a logical block address used to access the data block.

8. The method of claim 1 wherein the at least one other type of IMD to be verified is selected based upon an expected type of data corruption.

9. The method of claim 8 wherein the at least one other type of IMD to be verified is LBA IMD and the expected type of data corruption is a misdirected memory access operation.

10. The method of claim 8 wherein the at least one other type of IMD to be verified is checksum IMD and the expected type of data corruption is an erroneous WRITE operation.

11. A machine-readable medium containing instructions which, when executed by a processing system, cause the processing system to perform a method, the method comprising:
accessing a data block, the data block one of a plurality of data blocks mapped to a physical sector, each data block containing a user data segment and an associated IMD segment, each IMD segment including a version identifier IMD and at least one other type of IMD; and
validating the data block by verifying the version identifier IMD and at least one of the at least one other type of IMD.

12. The machine-readable medium of claim 11, wherein the at least one other type of IMD comprises checksum IMD.

13. The machine-readable medium of claim 11, wherein the at least one other type of IMD comprises logical block address IMD.

14. The machine-readable medium of claim 11, wherein the at least one other type of IMD comprises checksum IMD and logical block address IMD.

15. The machine-readable medium of claim 11 wherein verifying the version identifier IMD includes determining that a first version identifier stored within the data block matches a second version identifier stored outside of the data block.

16. The machine-readable medium of claim 12 wherein verifying the checksum IMD includes determining that a checksum stored within the data block matches a checksum obtained by applying a process to a user data contained within the user data segment of the data block, the process being a same process used to create the checksum IMD.

17. The machine-readable medium of claim 13 wherein verifying the logical block address IMD includes determining that a logical block address stored within the data block matches a logical block address used to access the data block.

18. The machine-readable medium of claim 11 wherein the at least one other type of IMD to be verified is selected based upon an expected type of data corruption.

19. The machine-readable medium of claim 18 wherein the at least one other type of IMD to be verified is LBA IMD and the expected type of data corruption is a misdirected memory access operation.

20. The machine-readable medium of claim 18 wherein the at least one other type of IMD to be verified is checksum IMD and the expected type of data corruption is an erroneous WRITE operation.

21. A data storage system comprising:
a storage media;
a processing system; and
a memory, coupled to the processing system, characterized in that the memory has stored therein instructions which, when executed by the processing system, cause the processing system to a) access a data block, the data block one of a plurality of data blocks mapped to a physical sector, each data block containing a user data segment and an associated IMD segment, each IMD segment including a version identifier IMD and at least one other type of IMD, and b) validate the data block by verifying the version identifier IMD and at least one of the at least one other type of IMD.

22. The data storage system of claim 21, wherein the at least one other type of IMD comprises checksum IMD.

23. The data storage system of claim 21, wherein the at least one other type of IMD comprises logical block address IMD.

24. The data storage system of claim 21, wherein the at least one other type of IMD comprises checksum IMD and logical block address IMD.

25. The data storage system of claim 21 wherein verifying the version identifier IMD includes determining that a first version identifier stored within the data block matches a second version identifier stored outside of the data block.

26. The data storage system of claim 22 wherein verifying the checksum IMD includes determining that a checksum stored within the data block matches a checksum obtained by applying a process to a user data contained within the user data segment of the data block, the process being a same process used to create the checksum IMD.

27. The data storage system of claim 23 wherein verifying the logical block address IMD includes determining that a logical block address stored within the data block matches a logical block address used to access the data block.

28. The data storage system of claim 21 wherein the at least one other type of IMD to be verified is selected based upon an expected type of data corruption.

29. The data storage system of claim 28 wherein the at least one other type of IMD to be verified is LBA IMD and the expected type of data corruption is a misdirected memory access operation.

30. The data storage system of claim 28 wherein the at least one other type of IMD to be verified is checksum IMD and the expected type of data corruption is an erroneous WRITE operation.
